(19) United States
(12) Patent Application Publication
(10) Pub. No.: US 2019/0064234 A1
(43) Pub. Date: Feb. 28, 2019

(54) SYSTEM AND METHOD FOR ASSESSING ELECTRICAL ENERGY OR POWER CHARACTERISTICS OR FEATURES OF ELECTRICAL DEVICES

(71) Applicant: ECOCENTRIC GROUP LIMITED, Fremantle (AU)

(72) Inventor: Paul LYONS, Fremantle (AU)

(21) Appl. No.: 16/083,449

(22) PCT Filed: Mar. 3, 2017
(86) PCT No.: PCT/AU2017/050190

§ 371 Date: Sep. 7, 2018

(30) Foreign Application Priority Data
Mar. 3, 2016 (AU) 2016900805

(51) Int. Cl. G01R 21/133; G01R 19/25; G01R 23/20; G01R 21/06

(52) U.S. Cl. CPC G01R 21/133; G01R 19/2513; G06Q 50/06; G01R 21/06; G01R 23/20

(57) ABSTRACT

Electrical data is gathered by a portable electrical energy consumption diagnostic device at a site. Each device is electrically connected into a respective electrical switchboard. One or more slave portable electrical energy consumption diagnostic devices can be connected to other switchboards at the same respective sites or other sites and communicates with a respective master device. Communication between master and slave devices is preferably wireless communication via a micro-network. Each master device communicates wirelessly electrical data obtained via the switchboard to a remote data collection server. The system identifies one or more electrical use or load features or characteristics and/or one or more electrical signature features of one or more electrical devices connected to an electrical circuit. One or more electrical devices is/are connected to an electrical circuit. Any electrical device connected to the circuit can be monitored and its electrical characteristics can be assessed.

### FIELD OF THE INVENTION

The present invention relates to assessment of characteristics of electrical energy usage of one or more electrical devices, such as identification, analysis and reporting of electrical energy usage, electrical power, current and/or voltage characteristics.

The present invention is particularly, though not solely, applicable to diagnosis of electrical energy usage characteristics and/or electrical efficiency characteristics of electrical devices, circuits and/or installations.

The present invention is applicable to, though not limited to, real time or near real time electrical energy/power/current/voltage monitoring, assessment and reporting.

### BACKGROUND TO THE INVENTION

Electrical energy consumption and the financial cost associated therewith are of growing concern to many people, businesses, households and in deed, countries as a whole.

Wasted electrical energy not only costs the user more money than is necessary but also uses up valuable natural resources for energy generation or requires more renewable energy installations than is necessary.

Most buildings or installations (including residential housing) using electricity have simple electricity meters to measure the amount of electricity consumed in order to calculate the cost of the electricity to be charged to the consumer. These meters can be monitored for the amount of energy used, and the periodic consumption figures tracked so that present electricity consumption can be compared to past electricity consumption.

Such graphs are usually shown on electricity bills from the electricity provider, but do not aid in real time measurement of electricity consumption or what equipment or where in a building consumption may be excessive and therefore what is the most appropriate solution(s) for that particular site.

Known building metering systems at best gather and report on intervals most commonly measuring total electrical energy consumption for a 30 minute period based on a pre-determined tariff from an energy retailer for the whole building.

Excessive consumption is one indicator of failing electrical equipment or need to upgrade old equipment, or a need to balance consumption.

Energy audits can be carried out on a building or installation. Such audits are largely theoretical in nature, not based on specific data extracted from the site or the site's infrastructure, are complex and current at best only for a point in time.

In a normal alternating current power system, the current varies sinusoidally at a specific frequency, usually 50 or 60 hertz. When a linear electrical load is connected to the system, it draws a sinusoidal current at the same frequency as the voltage (though usually not in phase with the voltage).

Current harmonics are caused by non-linear loads. When a non-linear load, such as a rectifier, is connected to the system, it draws a current that is not necessarily sinusoidal. The current waveform can become quite complex, depending on the type of load and its interaction with other components of the system. This is an example of how different electrical loads display different features and how these features change as the device changes its mode of operation including entering a non-standard or fault mode.

Further examples of non-linear loads include common office equipment and household equipment such as fridges, air conditioners, computers and printers, fluorescent lighting, battery chargers and also variable-speed drives/motors. In fact, many commercial and industrial electrical devices exhibit non-linear load characteristics.

Unexpected or uncharacteristic electrical loads, or changes to their features such electrical loads relating to electrical equipment or related electrical circuits, can be an indication of a fault or impending electrical failure.

Power quality can greatly affect the function and reliability of electrical equipment. Power quality determines the fitness of electric power to such electrical equipment, and therefore determines the ability of the equipment to function properly. Without the proper supply of power, an electrical device (or load) may malfunction, fail prematurely or not operate at all.

There are many ways in which electric power can be of poor quality and many more causes of such poor quality power. Being able to monitor such power supply and the performance of electrical equipment (loads) utilising that power supply can be very advantageous in pre-empting premature equipment failure and/or need to modify how and when the equipment operates and contribute to the more efficient running of that equipment.

With the aforementioned problems in mind, it has been realised that it is desirable to provide a means and/or method for improved assessment of electrical energy usage, such as identification, analysis and/or reporting of electrical energy usage based on the unique features that each electrical device has.

It is further desirable to provide means and/or methodology to identify characteristics of power supply and/or electrical equipment performance to enable pre-emptive action to modify the power supply and/or modify electrical equipment/load performance and/or modify or replace the electrical load/equipment.

### SUMMARY OF THE INVENTION

With the aforementioned in mind, as aspect of the present invention provides a method of assessing an electrical device connected to an electrical circuit, the device in operation providing an electrical load, the method including assessing at least one electrical feature of the electrical device, and determining at least one electrical characteristic and/or identity of the electrical device from the at least one electrical feature.

Preferably, assessing the electrical device includes identifying the electrical device. Preferably such identification includes determining or assigning one or more identifiers, such as type of device (e.g. pump, compressor, heater), make of device (e.g. manufacturer or supplier), model (e.g. product name and/or range identifier), specification (e.g. performance, rating, size) and any other characteristics useful for identifying and managing the electrical device.

One or more unique electrical characteristics associated with the device(s) may be stored in a record.

The record may include other identified of records of said unique characteristics of multiple electrical devices. The recorded characteristics may be used as a reference or benchmark signature for other electrical devices for assessment.

Electrical devices with the same or similar characteristics derived from the at least one feature may be identified as the same type of device or within a family of devices.

The assessed at least one feature may include derivatives of and from current and/or voltage harmonics, and power harmonics of the electrical device including combinations of these.

A further aspect of the present invention provides a system for assessing or monitoring performance of electrical devices connected to at least one electrical circuit, the system including at least one electrical information collector connected a said electrical circuit, at least one processor receiving and processing electrical information relating to at least one electrical feature of operation of the respective electrical device, a transmitter sending the processed electrical information to at least one remote location, means for generating and optionally identifying a set of unique electrical characteristics derived from the at least one feature relating to the electrical device.

The system may include access to a store of characteristics or record of the feature(s) of a number of said electrical devices.

The system may include a comparator to compare characteristics of two said electrical devices. The compared electrical device may be similar devices exhibiting similar electrical use characteristics.

The system may include assignment means to assign an identifier to the electrical device being assessed or monitored. The system may automatically assign respective identifiers to identified electrical devices.

Multiple said systems may share access to the records/data containing the at least one feature/characteristic records. Therefore, the systems may form an interconnected network or part of a network able to identify and assign identifiers to electrical equipment connected in any one of the systems.

One or more algorithms may be employed to assess the characteristics of each electrical device and identify or create a set of unique characteristics associated with each said electrical device based on those features.

Another aspect of the present invention provides a network of multiple said systems the systems sharing access to the records/data containing the characteristics/features records.

A said system may include manual input means to receive manual input data, such as details for completing an identifier for the electrical device. Such details may be required when the electrical device of that type, model, make or specification has never previously been connected to the system. Thereafter, the system may preferably ‘know’ that electrical device and can assign the same or similar identifier to a like electrical device subsequently connected to the same or another system within the network.

A still further aspect of the present invention provides a method of monitoring electrical energy usage includes the steps of: obtaining electrical usage data relating to at least one electrical energy usage characteristic of at least one electrical device in use; and identifying at least one electrical energy use signature relating to the at least one electrical energy usage characteristic of the at least one electrical device in use.

Preferably the one or more electrical features used to identify the unique characteristics of the at least one electrical device includes current and/or voltage characteristics of the respective device.

The one or more electrical energy use characteristics of the at least one electrical device may be obtained over at least one time period, and preferably in real time or near real time. For example, characteristics of current and/or voltage use of one or more devices may be monitored over a required period of time, which may preferably be in real time (or near real time allowing for any electrical data processing and transmission delays).

The one or more electrical features used to identify at least one electrical device may include electrical current and/or voltage harmonics characteristics.

The electrical energy use characteristics of the electrical device or each electrical device may include electrical current and/or voltage harmonics characteristics.

Such characteristics may include one or more sampled current and/or voltage values over time. For example, time base sampling of current and/or voltage relating to the electrical device(s) may be conducted. Such sampling may be in real time or near real time. Near real time will be understood to relate to a practical delay in data processing, transmission and reporting of the data. Such practical delay may be in the order of seconds, minutes or a few hours. In essence, no long term delay of many hours or days is inherent in the methodology and system/devices of the present invention. Any such longer term delay may be part of a user imposed data handling system whereby real time or near real time electrical usage data monitoring and reporting is not preferred; however, such data is obtained and available from the method, system and device(s) of the present invention.

Time based sampling may be conducted at a relatively high sampling rate. A spectrum of harmonics of the electrical waveform of a device or devices can be obtained at such higher sampling rates.

Preferably the method and/or system of the present invention samples a number of harmonics, such as harmonics 1-49, of the waveform. Sampling a number of harmonics at high frequency helps to identify numerous features that assist in distinguishing between devices and/or the mode of operation of a device in order to provide a desired signal resolution.

Preferably each of a number of harmonics in an electrical waveform relating to one or more devices is sampled to identify characteristics of the harmonic(s). The characteristics from multiple harmonics can be associated with the device as an electrical signature for that device.

Variations from the known characteristics can be used to identify potential or actual changes in operation of the device. For example, an electrical motor may start to draw increased current or exhibit voltage spikes as it begins to fail. Maintenance or replacement can be timely scheduled.

Obtaining the electrical energy use characteristics may include obtaining electrical use data from one or more electrical circuits with at least one said electrical device providing an electrical load in each said circuit.

Electrical energy usage data may be obtained using one or more devices or systems disclosed in International patent application number PCT/AU2013/001139 published as WO 2014/053021, the contents of which as incorporated in their entirety herein by reference.

It will therefore be appreciated and understood that one or more embodiments of the present invention may provide for real time continuous monitoring and reporting on electrical consumption for a required period of time.

Electrical data may be acquired and reported showing periodicity and/or increase in consumption for a whole building, a floor or section of the building, right down to particular pieces of equipment.

Therefore, at least one temporary electrical connector of the present invention may be connected into a switchboard of a building or installation at whole building/installation level, a sub-level covering a zone or portion of the building/installation, right down to the individual electrical supply to a particular piece of equipment.

One or more forms of the present invention may include one or multiple temporary electrical connectors for temporarily connecting to a variety of electrical supplies at a switchboard of a building or installation.

Another aspect the present invention provides portable electrical data diagnostic apparatus connectable to electrical systems to acquire and analyse electrical data there from, the apparatus including: at least one electrical connector to temporarily connect to an electrical supply for electrical equipment;
electrical data acquisition means; and
electrical data processing means to determine one or more electrical energy usage characteristics of one or more electrical devices providing an electrical load; and
the electronic identification means identifying an electrical usage characteristics of the one or more electrical devices from the electrical usage characteristics.

Preferably the electrical energy usage characteristic(s) is/are acquired over a period of time.

One or more forms of the present invention may include transmission means to transmit the acquired electrical data to a remote electrical data processor for remote electrical data processing.

The acquired electrical data may be processed to diagnose electrical consumption issues and produce electrical consumption and/or cost related reports e.g. for the easy understanding by the non-technical reviewer.

Advantageously, the present invention provides a portable electrical consumption diagnostic device for energy efficiency analysis that is non-disruptive to operational activities of a business or a building/installation and which preferably provides automated analysis in real-time and an account of electrical energy consumption to make informed decisions, such as on capital expenditure and/or maintenance scheduling for electrical equipment.

The present invention is beneficial for use in energy audits because electrical data can be acquired in real time or near real time, and reports on electrical consumption can be generated with very little, if any, practical delay.

A further aspect of the present invention provides a method of analysing and reporting electrical data relating to electrical energy usage, the method including: connecting a portable electrical energy diagnostic apparatus to at least one electrical circuit of the building or installation, obtaining for a period of time electrical data relating to electrical energy usage characteristics of at least one electrical device connected to at least one electrical circuit, analysing the obtained electrical data, and reporting on the electrical energy usage characteristics based on the analysed electrical data, the method including identifying a set of known electrical energy usage characteristics of one or more of said at least one device, and providing an electrical energy usage modification strategy for use in determining need for modification of electrical energy usage characteristics in the at least one circuit.

The portable electrical energy diagnostic device may be temporarily connected to one or multiple said electrical circuits and/or devices.

Prior to obtaining and analysing electrical data, the electrical energy diagnostic device may be set-up to obtain the electrical energy data by conducting an initial device set up procedure, a references set up procedure, a branch circuits set up procedure and a communications set up procedure.

The initial set-up may occur when a new data acquisition, analysis and reporting task is created and reference information has been input into the apparatus from which calculations and processing is conducted. Initial set-up data may include (but not be limited to) one or more of: project name, address, type of building(s)/installation(s), switchboard Number/Location, electrical tariff.

The reference set-up stage may include an electrical interfacing stage including a combination of manually entering information into the device and providing data sourced from at least one CT transducer connected to the electrical energy diagnostic apparatus.

The reference set-up stage may provide a reference from which aggregated information from electrical circuit branch monitors must equate.

Manually entered data may include one or more of electrical supply name, size of feed in the electrical cables to be monitored, number of feed in cables or type of supply.

At least one of a temperature or humidity sensor may be connected to the electrical energy diagnostic apparatus and temperature and/or humidity data acquired to be used in the analysis of the electrical energy consumption data.

Electrical ‘branch’ circuits set-up may include manually entering information into the diagnostic apparatus and/or data collected from the current transformers (CTs). Manually entered the electrical data may include entering one or more of a circuit name, circuit location, circuit type and electrical phase.

An interface for CTs may be provided for connecting the diagnostic device to various electrical circuits in a switchboard.

The method may include ensuring that the diagnostic device is enabled locally and via remote connection to a remote server.

A signal may be provided that indicates electrical data is being received and the logic of this data is as expected or within one or more required parameters. The diagnostic apparatus may be connected to the remote server if there are no faults indicated in the data or with the device.

Electrical data obtained when the diagnostic apparatus is connected to the circuits in the switchboard may be transferred at intervals based on set-up parameters to a database stored within the diagnostic device or stored remotely.

The database may be accessible locally and/or remotely via the processor whereby the electrical data is available for processing and being presented locally or synchronised with the remote server and processed and presented remotely.

At least one electrical energy use characteristic may be used to determine a maintenance or replacement strategy for the at least one electrical device.

One or more features of an electrical energy use waveform may be sampled to identify one or more electrical characteristics of a device.

Multiple features from one or more harmonics may be sampled, such as, for example, from up to 49 harmonics of the electrical energy use waveform.

One or more forms of the present invention may include modifying the a known electrical characteristic(s) of a device by relating the device identity from sampled waveform harmonics of one or more other devices at other locations and/or in other circuits.

Deviations over time from the sampled at least one feature may be used to identify or indicate degradation or potential failure of device.

A further aspect of the present invention provides a system of components to conduct the aforementioned method(s).

Another aspect of the present invention provides a method of assessing an electrical device connected to an electrical circuit, the device in operation providing an electrical load, the method including assessing electrical harmonics of the electrical device, and determining an electrical signature of the electrical device from the harmonics.

A still further aspect of the present invention provides a system for assessing or monitoring performance of electrical devices connected to at least one electrical circuit, the system including at least one electrical information collector connected a said electrical circuit, at least one processor receiving and processing electrical information relating to electrical harmonics of operation of the respective electrical device, a transmitter sending the processed electrical information to at least one remote location, an electrical

A further aspect of the present invention provides a method of monitoring electrical energy usage includes the steps of: obtaining electrical usage data relating to at least one electrical energy usage characteristic of at least one electrical device in use; identifying at least one electrical energy use signature relating to the at least one electrical energy usage characteristic of the at least one electrical device in use.

Another aspect of the present invention provides a method of analysing and reporting electrical data relating to electrical energy usage, the method including: connecting a portable electrical energy diagnostic apparatus to at least one electrical circuit of the building or installation, obtaining for a period of time electrical data relating to electrical energy usage characteristics of at least one electrical device connected to at least one electrical circuit, analysing the obtained electrical data, and reporting on the electrical energy usage characteristics based on the analysed electrical data, the method including identifying an electrical energy usage signature of one or more of said at least one device, and providing an electrical energy usage modification strategy for use in determining need for modification of electrical energy usage characteristics in the at least one circuit.

It will be appreciated that there are many features as subsets of the harmonics of an electrical signal—for example, looking at 49 harmonics, more than 480 features can be identified and examined according to one or more embodiments of the present invention. Furthermore, this approach can be applied to all states of operation of a device—for example, the features of a washing machine on spin cycle is quite different to its rinse cycle of the same machine. One or more features, such as dynamic feature sets, can be used to:
identify what a device is (including disaggregation of multiple devices on a single circuit)
what mode of operation it is in and if that mode is a non standard e.g. potentially a fault mode

Benefits include
true device monitoring and management—condition based monitoring
efficient installation (loads may be auto identified).
more effective diagnosis for energy efficient and site management/productivity outcomes.

### BRIEF DESCRIPTION OF THE DRAWINGS

FIG. 1 shows a general view of the primary components within a portable device according to an embodiment of the present invention.

FIG. 2 shows a more detailed layout of components and connectivity in the diagnostic device than in FIG. 1 according to an embodiment of the present invention.

FIG. 3 shows a diagrammatic depiction of the connectivity of a portable device to a building power switchboard according to an embodiment of the present invention.

FIG. 4 shows a flow chart of the set-up stages for an embodiment of the present invention.

FIG. 5 shows a general layout of a report on electrical energy consumption after processing of the electrical data according to an embodiment of the present invention.

FIG. 6 shows an alternative detailed layout of components and connectivity in the diagnostic device according to an embodiment of the present invention.

FIG. 7 shows a diagrammatic depiction of the connectivity of a portable device to a building power switchboard according to an embodiment of the present invention.

FIG. 8 shows a flow chart of the set-up stages for an embodiment of the present invention.

FIG. 9 shows a general layout of a report on electrical energy consumption after processing of the electrical data according to an embodiment of the present invention.

FIG. 10 shows a schematic representation of network architecture according to an embodiment of the present invention.

FIG. 11 shows a representation of display of information and recommendations to a user/client.

FIG. 12 shows a system according to an embodiment of the present invention.

FIG. 13 shows a flowchart of functionality of at least one embodiment of the present invention.

FIG. 14 shows a chart of harmonics of electrical power versus time for an electrical device, the harmonics used to determine a signature for the electrical device.

FIG. 15 shows an example of sampling of a harmonic of an electrical waveform relevant to an embodiment of the present invention.

### DESCRIPTION OF PREFERRED EMBODIMENT(S)

One or more embodiments of the present invention will hereinafter be described with reference to the accompanying figures.

A portable container, such as a hard briefcase style container, houses a power supply, a modem-router, a data processor (preferably a miniature data processor), and at least one energy transducer. Multi-purpose connection points are provided to the exterior of the case for input of at least one satellite connector module and other power, communication and voltage references as required.

Cables and Split-core Current Transformers (CTs) may be carried in the container or may be carried separately carried.

The device of the present invention is portable and efficient to connect to an electric switchboard. This provides a non-disruptive service to a client to which the electrical consumption analysis and reporting is to be provided. The device preferably provides automated reporting in that, once connected to the switchboard, the device is autonomous in the sense that it will automatically and continuously acquire electrical consumption data for the required period. The device may be controlled remotely to vary its reporting specification. The device may be securely accessed via the internet and the modem-router to obtain reports/data and to vary any parameters for acquiring and/or reporting data.

The diagnostic device may include provision for server back-up for security & technical assessment of installation. Having the diagnostic device connected to a central server provides multiple benefits to both an end user (in the sense of benefiting from the audit and reporting service from the device) and from operating a control centre:
i) Any logged data is saved as a back up to the device
ii) The device has access to periodical updates of firmware or software
iii) A central control centre retains control in the event of unsolicited use of a device. This may be through use of a unique (preferably per diagnostic device) activation key/code that should preferably be kept current through periodic connectivity with the central server(s).
iv) Collected data can be ‘banked’ or consolidated to create a comprehensive data base of multiple energy users for additional development and market knowledge
v) Provision for alarm notifications to a customer or operator in the event of unusual or device responses

The device may include software having a beneficial set-up wizard for new users.
i) The wizard will have a feedback mechanism to the installer that reveals mistakes in the set up process. This may help avoid mistakes in the set up process. For new users or those unfamiliar with the set-up or the device, the feedback mechanism may also provide visual and textual instructions throughout the set up procedure.
ii) Final stage of the set up involves having to connect to the server before logging can begin

Device Software

Communication between device components is preferably via open protocol MODBUS standard, preferably carried on two wires between branch monitor, temperature/humidity sensor and the data processor.

The data processor preferably uses a Linux-based operating system and an SQL-based database to store and process the recorded data. The data processor may also have a web-server to provide a portal on the local network to configure and manage the device.

Device Web-Based Portal

The device can be configured and managed via a local web-based portal accessible via a web browser on a portable computer, such as a laptop or tablet device, connected either directly to the device (Ethernet) or via the wireless router (Wifi). This portal includes: one or more of a set-up and configuration wizard, a live dashboard providing charts/tables, and a data analysis reporting and/or data export tool, such as via pdf, Word, Excel, CSV

Central Server

The central server preferably includes a Linux virtual PC with Apache, MySQL and Perl/PHP communicating securely via transport layer security (TLS) or secure sockets layer (SSL). This architecture is intended to scale with the volume of devices it is handling. However, the central server could instead be a Windows server, running IIS, SQL Server/Oracle and Java.

All devices when connected to the internet communicate with the central server for the following reasons:
Automatic Updates (preferably of all software on the device)
Synchronisation and Backup (of all data collected)
Remote Support, Diagnostics, Quality Assurance and Control
Data Consolidation (eg. for multiple device projects)

Online Internet Based Portal

The central server's web-server provides a secure online portal for the device owner/operator, licensee and/or end user client to access services online regardless of the status of the respective device including:

A live digital/user interface providing accessible charts and tables detailing the electrical energy consumption in various formats, such as consumption versus time, individual equipment electrical consumption, building/installation zone electrical consumption, increase in consumption identifying possible failure of equipment to enable pre-emptive maintenance to be scheduled.
Reporting analysed data and/or exporting analysed or un-analysed data for remote reporting or remote analysis and reporting.
Report creator for creating a document visualisations and explaining the analysis results. This may include editable analysis and recommendations for energy efficiency improvements.
Remote Administration for remotely configuring and managing the device or multiple said devices.
Licensing, Booking and Accounts Management

Set-Up Procedure:

There are four stages of the set-up procedure: 1. Initial Set-up, 2. References Set-up, 3. Branch Circuits Set-up, 4. Communications set-up.

### 1. Initial Set-up

Initial set-up occurs when a new data acquisition, analysis and reporting task is created and all the common descriptive details are entered into the project. Initial set-up parameters are important at this stage to the overall processing of data initial set-up includes reference information from which calculations and processing is acquired. The data in this section includes: Project Name, Address, Type of Building(s)/Installation(s), Switchboard Number/Location, Tariff. Additional Information

### 2. References Set Up

The reference set up stage is the first electrical interfacing stage where the hardware must be installed. It is therefore a combination of both manually entered information and data that is sourced from the CT transducer.

Manually entered data includes: Supply Name, Size of feed in the electrical cables to be monitored, Number of feed in cables, Type of Supply (If Applicable) i.e. HVAC, Lighting, etc.

Hardware Components:
Temperature and Humidity data is acquired through the transducer which provides the information via the open communication protocol known as MODBUS.
Reference Voltage is a connection that must be hard wired into an available circuit breaker in the applicable switchboard.
Main Current Transformers—come in different sizes and are governed by the size of the main incoming cables that they are measuring.

The information in this reference set-up stage serves as master reference(s) from which aggregated information from the branch monitors must equal. The architecture of the system is hierarchical in that these mains references sit at the top
i) The Hierarchy structure may include that the parent (or master) CT value must be equal or greater than the sum of the lower CT values. This means that any deviation from this equation triggers a fault in the set up process. i.e. CT(m)≥CT(1)+CT(2)+ . . . CT(n)

### 3. Branch Circuits Set-Up

As with the references set-up, the branch monitors require both manually entered information and data collected from the current transformers.

Manually entered data includes: Circuit Name, Location, Type, Electrical Phase.

### Hardware Components:

Interface Module. This is preferably, though not limited to, a 9-way enclosure that allows the installer to locate groups of CT's at various locations around the switchboard. Other numbers of sockets/outlets/inlets may be used. The module preferably has a number (preferably 9) of 2.5 mm Socket Power Chassis connectors.
CT's. Each CT can be 50 A, 100 A, 200 A or 500 A, which may vary, and each has preferably a split core so that they can be attached without the need to disconnect the cable. Each CT has a 2.5 mm plug power chassis connector for connection into the associated module. Preferably the present invention utilises 36 Branch CT circuits, though capacity for 72 or 84 or more monitored branches can be provided by specifying the components of the device and providing suitable connections.

### 4. Communications Set Up

The purpose of this stage is to ensure that the device enabled both locally but also via remote connection to the central server. As such there is an enable signal that indicates logging has begun. This means that the database is receiving data and the logic of this data is within the expected range. Providing there are no alarms or false data indicators on the device, the device connects to the central server. Once this connection is made then the device set-up is complete and the device installer may secure the site and leave the device in operation. However, it is preferred that a final communications check is confirmed before leaving the installed device as connection to the server may be compromised by replacing covers etc.

There may be instances when it is impossible for the diagnostic device to connect to the central server (such as a remote or poor reception area or difficult location. In such instances, connection to the central server can be overridden and the diagnostic device will obtain, analyse and store data, or obtain and store raw data for post analysis.

Data Processing

Electrical data is transferred at intervals based on the set-up parameters, eg every second, via the processor (e.g. MiniPC) to an SQL-based database stored on a fixed hard disk within the device itself. This database can then be accessed both locally and remotely via the processor. The data can then be processed and presented locally or synchronised with the central server and processed and presented remotely. In both cases, identical algorithms and database structures are used to store and process the data.

Data processing is for two purposes: (1) the live web-based dashboard; (2) for the automated generation of reports and recommendations documents.

The live digital/user interface consists of numerous charts and/or tables presented via a web portal and/or native application that show various trends and ratios split by multiple characteristics in regard to energy consumption.

The reports generator consists of a document template where charts, data tables and form fields are inserted in various sections to provide a complete report that can then be saved on to the user's computer and manually edited further if required.

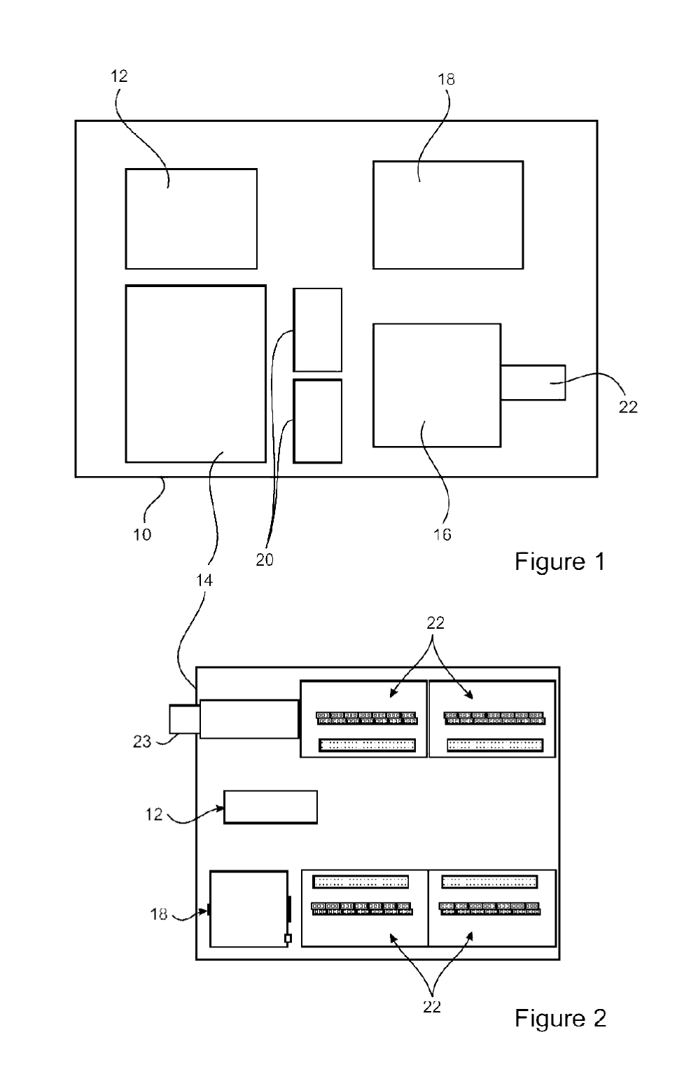

The diagnostic device 10 as shown in general layout in FIG. 1 includes an on-board power supply 12, an energy monitoring board 14, a MiniPC 16, and modem/router 18, CT adaptors 20 and an interface module 22, all housed within a portable container 24. Typically the portable container is an impact resistant carry case (such as a carry case of plastic or metal, or combinations thereof).

FIG. 2 shows connectivity between the components within the device 10. FIG. 2 also shows connection for external components, such as CT inputs 26 and mains CT inputs 32, as well as connections for Ethernet LAN and USB 3G dongle 28, and for the temperature and/or humidity sensor(s) 34.

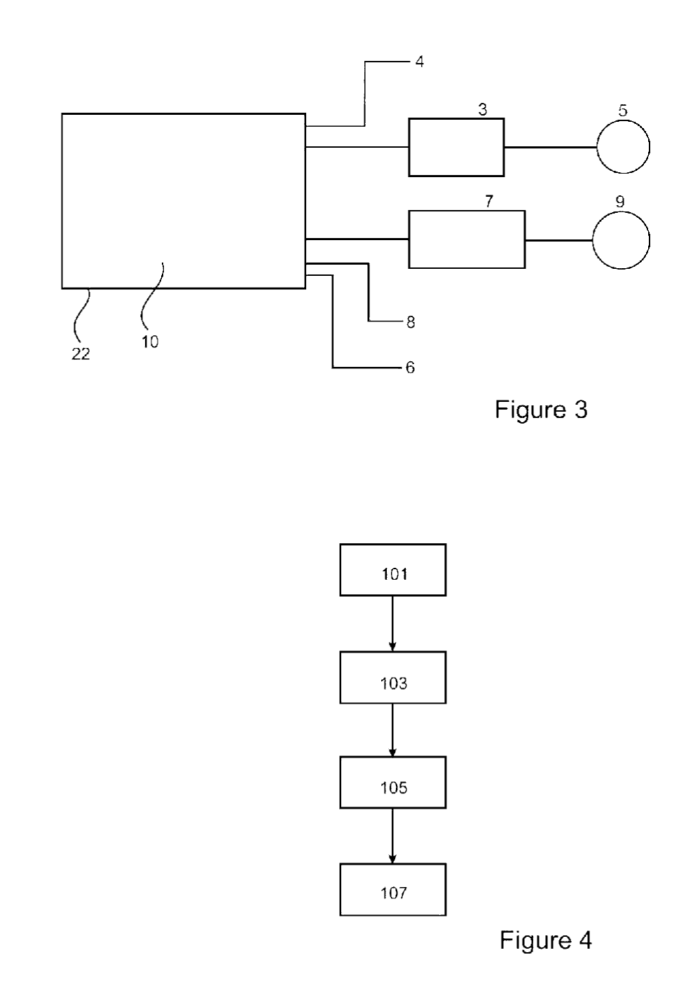

FIG. 3 shows connection of various CTs to various respective electrical circuits of a switchboard. The switchboard contains the circuit breakers for the various floors and pieces of equipment in a building or installation.

Mains 1 36 and Mains 2 38 provide three phase CT connection to monitor the three phase mains inputs, being mains 1 main Feeder and Mains 2 Ground Floor Feeder. CT connections are made to the various rooms 40a to 40f on a floor, and to various pieces of equipment, such as an elevator 42, lighting 44 etc. Within a room, such as an apartment, individual equipment can be monitored, such as room lighting 46, air conditioning 48 and a cooking stove/oven 50. The CT leads of the diagnostic device connect to the various electrical circuits for all of these rooms, floors and equipment.

FIG. 4 shows a flow chart of setting up the diagnostic device. The device 10 is first switched (powered up) 52. Project information 54 is then entered at an initial set-up phase 53. Project information includes a set-up wizard 56 to guide a user how to make the necessary connections and set-up procedure. Project information includes location, address, project name, job details (type of switchboard, number of connections, type of building or installation). Once initial set-up is completed, the device enters a References set-up phase 55. Reference cables are connected 58, including connecting an environmental sensor (such as temperature and/or humidity) 60. The Master CTs are connected 62 to the mains cables.

Once the master CTs as references are connected and reference setup is complete, set-up then proceeds to a Branch circuits set-up phase 57. CTs are connected 64 to the branch circuits. Once the branch circuits are connected, set-up of the device proceeds to a communications set-up 59 phase. The device then communicates 66 with a remote server. Once an enabled signal is received 68, set-up is complete 70.

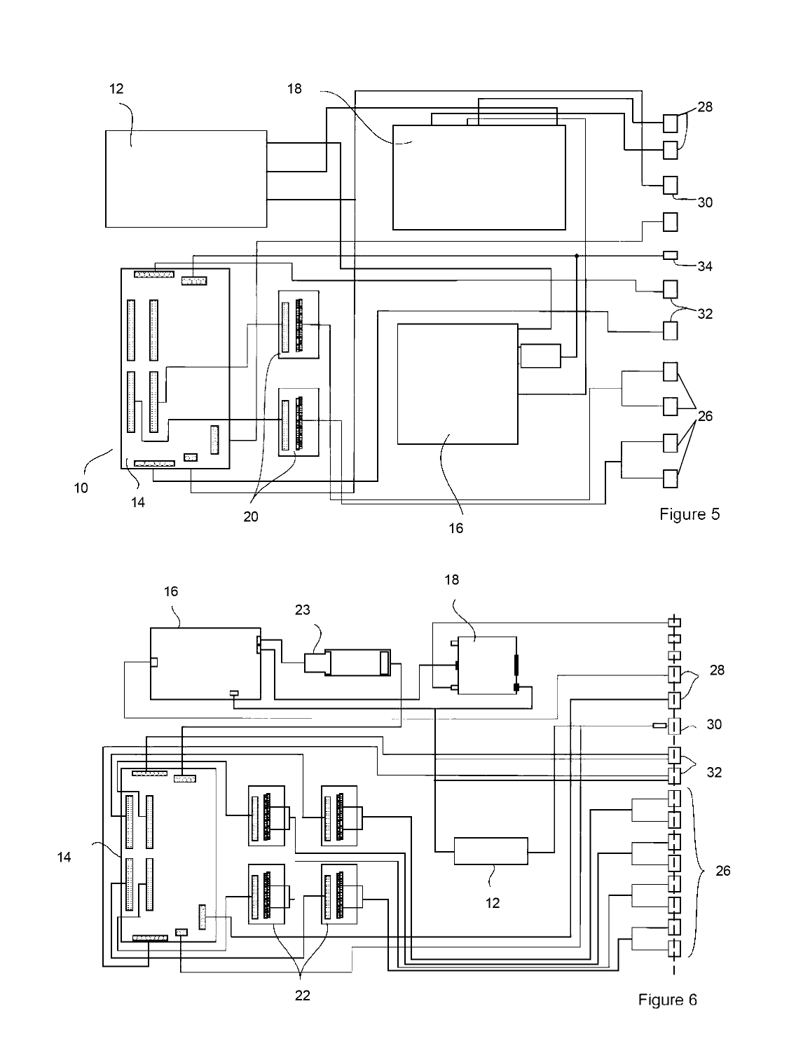

FIG. 5 depicts an embodiment of a proposed ‘live’ dashboard during or after the data acquisition. This function is effectively the tool with which a technical reviewer is able to input various energy change scenarios for the site in order to arrive at an optimum outcome for the site. It is therefore an intermediary stage where final analysis is conducted and then from this point a final report is able to be printed with the proposed recommendations.

FIG. 6 shows an alternative arrangement and connectivity of the components compared to FIG. 5.

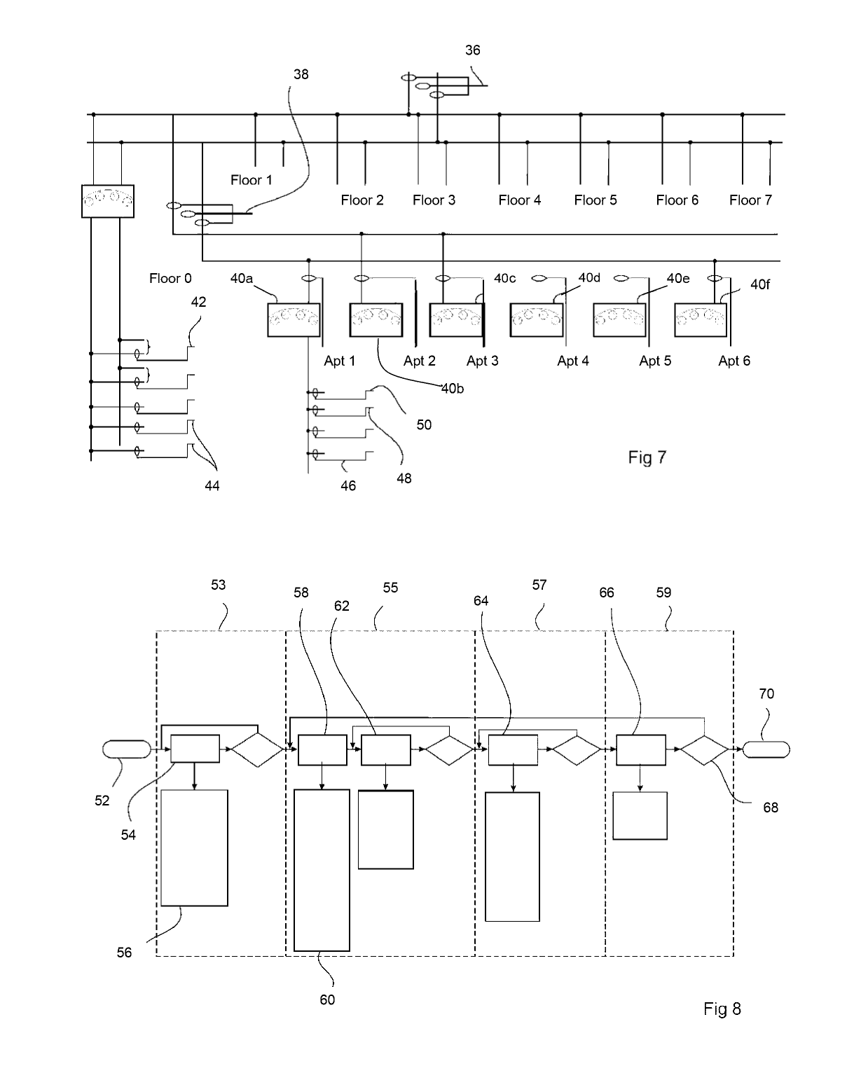

FIG. 7 shows connection of various CTs to various respective electrical circuits of a switchboard. The switchboard contains the circuit breakers for the various floors and pieces of equipment in a building or installation.

Mains 1 36 and Mains 2 38 provide three phase CT connection to monitor the three phase mains inputs, being mains 1 main Feeder and Mains 2 Ground Floor Feeder. CT connections are made to the various rooms 40a to 40f on a floor, and to various pieces of equipment, such as an elevator 42, lighting 44 etc. Within a room, such as an apartment, individual equipment can be monitored, such as room lighting 46, air conditioning 48 and a cooking stove/oven 50. The CT leads of the diagnostic device connect to the various electrical circuits for all of these rooms, floors and equipment.

FIG. 8 shows a flow chart of setting up the diagnostic device. The device 10 is first switched (powered up) 52. Project information 54 is then entered at an initial set-up phase 53. Project information includes a set-up wizard 56 to guide a user how to make the necessary connections and set-up procedure. Project information includes location, address, project name, job details (type of switchboard, number of connections, type of building or installation). Once initial set-up is completed, the device enters a References set-up phase 55. Reference cables are connected 58. including connecting an environmental sensor (such as temperature and/or humidity) 60. The Master CTs are connected 62 to the mains cables.

Once the master CTs as references are connected and reference setup is complete, set-up then proceeds to a Branch circuits set-up phase 57. CTs are connected 64 to the branch circuits. Once the branch circuits are connected, set-up of the device proceeds to a communications set-up 59 phase. The device then communicates 66 with a remote server. Once an enabled signal is received 68, set-up is complete 70.

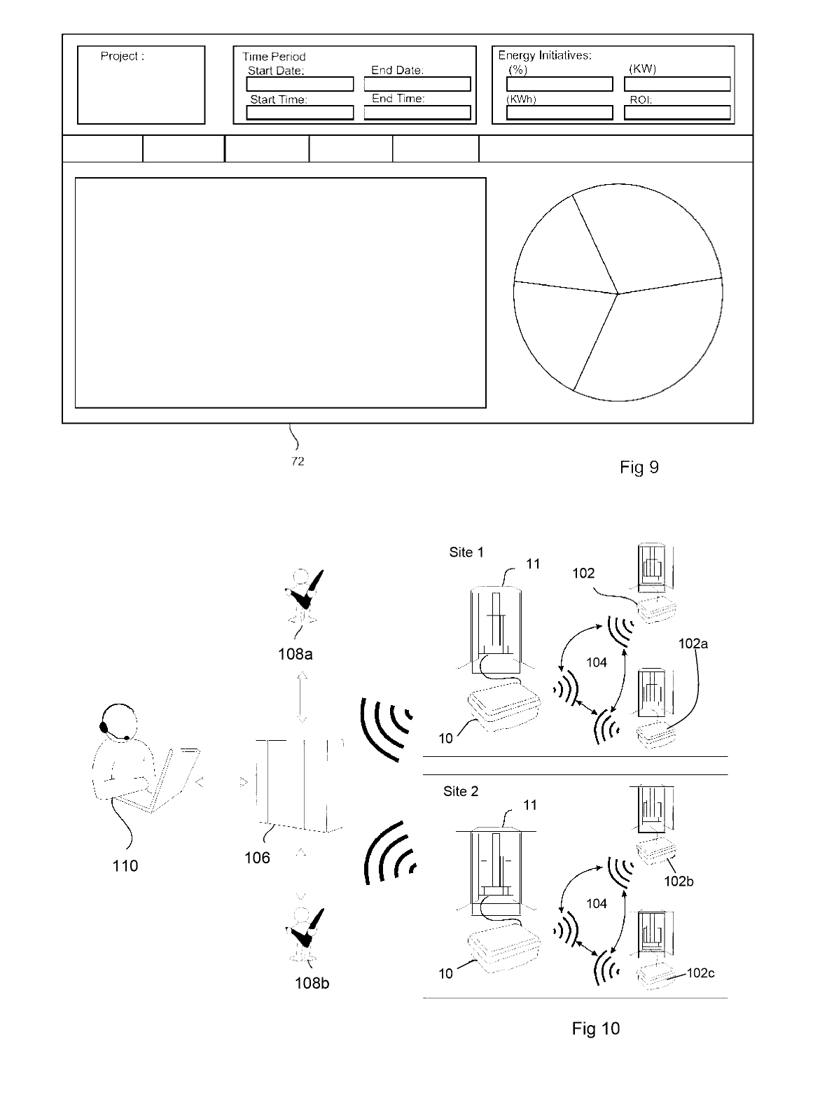

FIG. 9 depicts an embodiment of a proposed ‘live’ dashboard during or after the data acquisition. This function is effectively the tool with which a technical reviewer is able to input various energy change scenarios for the site in order to arrive at an optimum outcome for the site. It is therefore an intermediary stage where final analysis is conducted and then from this point a final report is able to be printed with the proposed recommendations.

Data analysis can be presented with a detailed report showing total amount of energy consumed, periods of energy consumption, changes in energy consumption (including sharp or gradual increase in consumption—suggesting maintenance or care may be required, or a device is in too warm or cold a location). Energy consumption can be shown relating to current and/or voltage.

FIG. 10 shows a general schematic representation of network architecture embodying the present invention. This shows the network architecture at site level and at server level via a GSM platform to enable the obtained electrical data to be assessed remotely and reported upon.

Electrical data is gathered by a portable electrical energy consumption diagnostic device 10 at a site (say, S1). Further such devices 10a can be deployed at other sites (say, S2, for example). Each such device is electrically connected into a respective electrical switchboard 100, 100a. One or more slave portable electrical energy consumption diagnostic devices 102,102a, 102b, 102c . . . can be connected to other switchboards at the same respective sites or other sites and communicate with a respective master device 10. Communication between master and slave devices is preferably wireless communication via a micro-network 104.

Each master device 100 communicates wirelessly electrical data obtained via the switchboard 11 to a remote data collection server 106.

Authorised auditors 108a, 108b etc., can review and report on obtained electrical data by connecting to the server. One or more technicians 110 can maintain data and data integrity, as well as monitor for and deal with technical issues that may arise from time to time.

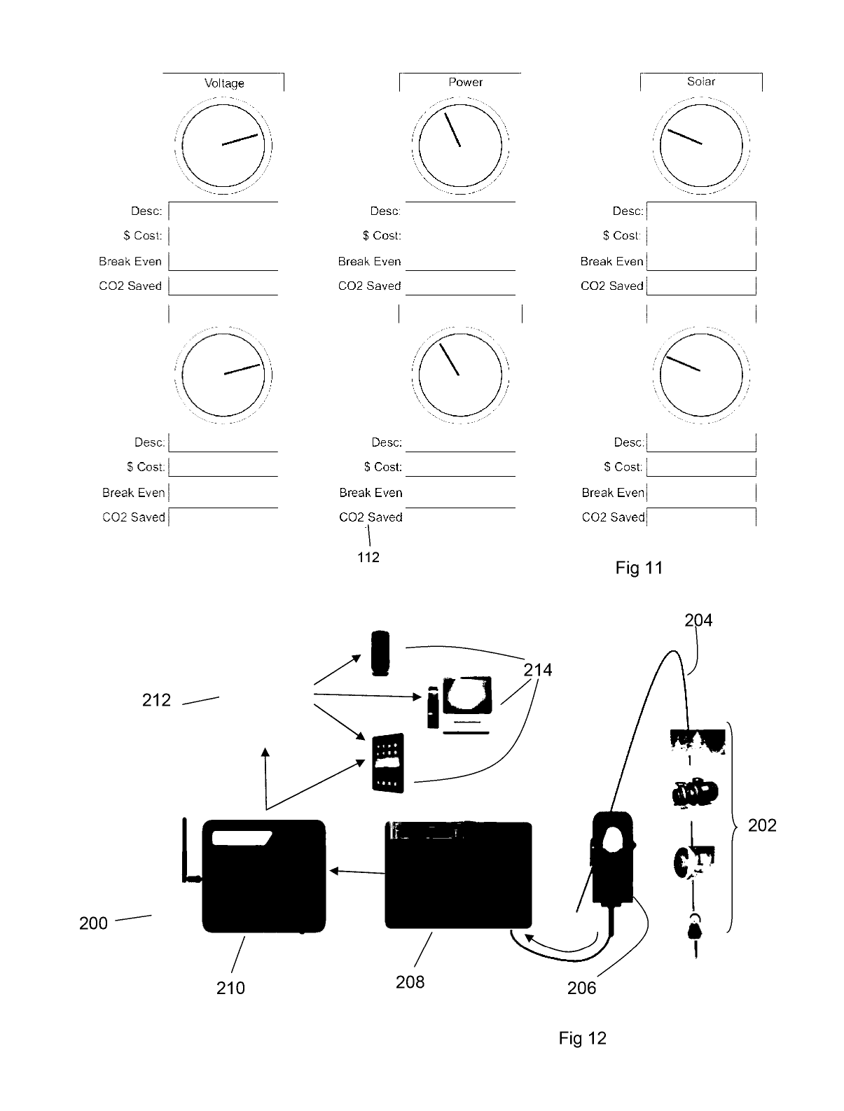

FIG. 11 shows a representation of a display ‘dashboard’ 112. This provides an interface for a user to appreciate and evaluate the energy, cost and CO2 saved through energy monitoring and control enabled through the present invention. The values shown in FIG. 7 are exemplary for the purposes of understanding the nature and benefit of the present invention.

FIG. 12 shows a system according to an embodiment of the present invention arranged and configured to identify one or more electrical use or load characteristics and/or one or at least one signature of one or more electrical devices connected to an electrical circuit.

One or more electrical devices 202 is/are connected to an electrical circuit 204. The device(s) can include, for example, household or commercial electrical appliances (such as electric heaters, kettles, refrigerators, freezers, air/conditioning, electric cookers, microwave ovens, washing machines, tumble dryers, dishwashers, swimming pool/spa pumps and/or chlorinators, garage door motors etc.). The device(s) might include commercial and/or industrial electrical devices, such lift motors, vehicle hoist motors, pumps, ovens, electrical process equipment, engineering machines (such as lathes, CNC machines, welders, milling machines etc.). Any electrical device connected to the circuit can be monitored and its electrical characteristics can be assessed.

A current transformer (CT) sensor 206 (such as a split core type CT) is used to sense electrical characteristics (such as current and/or voltage) in the circuit. Sensed electrical characteristics are provided to one or more collectors 208. Each collector can preferably monitor one or a number of electrical circuits, and each circuit may have one or more electrical devices connected thereto.

Each collector 208 provides data to a gateway 210. The data includes processed, partially processed, unprocessed or augmented electrical characteristics information from or relating to the electrical device(s) being monitored.

The or each gateway can transmit data to a remote location for reporting, storage and/or processing of the collected electrical characteristics information. The remote location can be one or more of cloud storage and processing or a display device, such as a smart phone, table, laptop or desktop computer etc.

Each gateway may also act as a receiver for signals coming in to the system, such as for a software update, communications check, or data integrity or systems performance check.

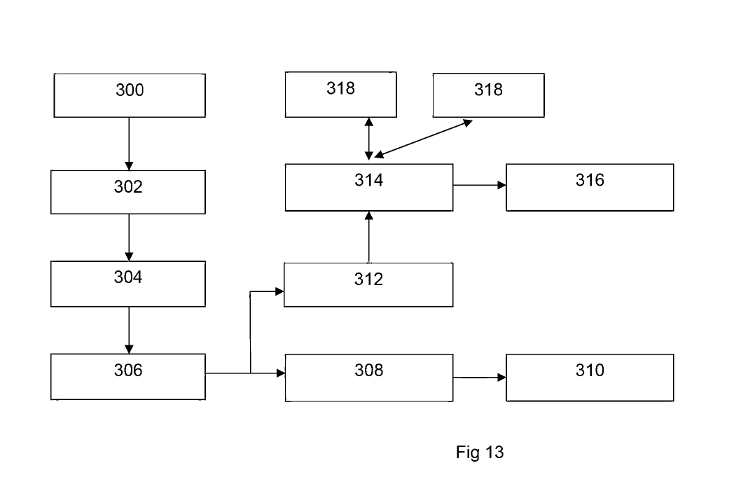

FIG. 13 shows a flowchart of typical operation of at least one embodiment of the present invention.

300—One or more of the collectors 208 is/are connected via the CT(s) to the circuit(s) to be monitored and/or analysed.

The electrical device or devices connected to the electrical circuit(s) using electrical energy (e.g. standby mode, in operation or switching) are monitored by sensing the electrical characteristics within the circuit(s) created by the devices providing electrical demand/load on the circuit(s). For example, current and/or voltage can be monitored over a period of time, either periodically or continuously, even if the electrical device is in standby.

302—Current and/or voltage demands of the electrical device(s) is/are monitored by sampling high frequencies.

304—Analytics (preferably in the hardware, such as in the collector(s) and/or gateway(s) and/or in a cloud based or remote Application Programming Interface (API) are conducted to identify electrical fingerprint/signature of each electrical device to be monitored/analysed.

304—Each of the electrical devices providing a load to be monitored/analysed can be cross referenced with a record of known electrical device signatures. However, if there is no matching electrical device signature already recorded, information relating to the electrical device can be manually entered (such as make, model, serial number, rating, location etc.) into the record. A manually entered record of the electrical device can be assigned to the electrical device for future recognition by the system. Similar electrical devices subsequently connected to the system will then be recognised based on the manually entered record.

306—Analytics can be conducted within the hardware of the system and/or remotely (such as cloud based API) to analyse performance of individual electrical devices (e.g. efficiency, power quality and electrical harmonic disturbance(s)).

308—Analysis of the electrical characteristics of an electrical device is benchmarked against the same or other like devices, such as those stored on record.

The record may include a ‘library’ of electrical device features and/or characteristics, and the present electrical device may be compared with the records for a number of like devices for an assessment of that device's performance.

310—Monitoring of circuit(s) and the electrical device(s) connected thereto is preferably ongoing (sampling over a required or indefinite period of time). One or more alerts may be provided based on one or more pre-determined conditions/thresholds being met, such as an unexpected rate of increase in voltage/current demand for a device, intermittent or unexpected power use, voltage spiking, electrical arcing, device failure, out of hours use, circuit overheating, excess energy consumption, peak load consumption etc. Alerts can be enabled by an end user, installer or service provider/agent, when authorised.

312—Advice on the relative status and performance of the device along with recommended actions specific to that device can be presented to the end user via a graphical user interface or other display medium.

314—Information relating to the electrical device(s) can be aggregated, preferably ultimately to encompass an entire electrical network being monitored (such as a site, building, floor or section of a building) to be used to produce advice on the performance of the covered electrical network and specific actions required based on the analytics.

316—Comparisons across a portfolio of sites (“buildings like this”, “floors like this”, “rooms like this”) can be made to provide early assessment of expected electrical performance of electrical devices.

Overall performance of electrical devices over time, including preferably return on investment (ROI), comparison with statistical failure rate, ROI on new energy investments and progression towards and ultimate attainment of zero net energy, can be conducted.

Data analysis of electrical energy usage and/or electrical load(s)/device(s) within or connected to an electrical circuit can be presented with a detailed report showing total amount of energy consumed, periods of energy consumption, changes in energy consumption (such as including sharp or gradual increase in consumption and/or load characteristics, voltage and/or current signature(s) etc.—suggesting maintenance or care may be required, device failure can be predicted and therefore maintenance and/or replacement scheduled in to a timetable or immediate attention, or a device is in too warm or cold a location).

Electric energy/power supply and/or consumption can be shown relating to current and/or voltage and time.

Electric power supply/usage for one or a number of electrical devices (equipment) and/or circuits can be sampled e.g. sampled digitally, at a sampling rate to obtain a power supply/power usage profile/signature for the equipment/circuit.

According to one or more embodiments of the present invention, at least one characteristic of electrical power/energy usage for one or more devices and/or circuits is/are identified. Such power/energy usage characteristics can be one or more of voltage, current and voltage/current harmonics.

The at least one feature (as modified by current/voltage fluctuations/interference/electrical resistances etc. from a true sinusoidal wave to a complex sinusoidal waveform) is sampled at a relatively high sampling rate to obtain sampling data that can be used to identify one or more electrical characteristics of the circuit and/or load (equipment) being monitored.

Such monitoring can be conducted by sampling electrical characteristics within/of the circuit, such as at a sampling rates above 10 Hz.

Preferably, the sampling rate is ata minimum of 12.8 kHz.

A relatively high sampling rate, such as 12.8 kHz or more, is preferred to access a sufficient spectrum of features and harmonics of the electrical waveform of a device or devices. Preferably the method and/or system of the present invention samples harmonics within the range of harmonics 1-49 of the waveform, such as to distinguish between devices and/or provide required signal resolution.

It will be appreciated that generating and identifying the electrical characteristics and monitoring over time, can be used to identify a particular type of circuit or type/model of equipment. For example, a lighting circuit containing fluorescent lights will have a particular high load demand at start-up and then reduce to a level load. Motors for lift winding gear will exhibit high load characteristics for regular short periods of time. Pump motors will exhibit continuous loads for long periods of time.

The maximum current, maximum voltage, time periods of off/running/start-up, and harmonics (as examples of features) in the electrical signature can be used to identify the load in the circuit/equipment, and over time such signatures can be monitored to identify changes in electrical power/energy usage characteristics, such as unexpected increasing current/voltage demand, spikes in current/voltage (either of which may indicate premature failing of the equipment), need for voltage/current optimisation (such as smoothing or voltage step-up/step-down for the equipment), and/or change in timing of operation of the equipment.

Variation in electrical power/energy usage can also be used to identify circuit problems, such as failing wiring/short-circuits, and thereby allow early intervention to prevent risk of equipment failure/fire.

Monitoring can be conducted in real or near real time. For example, sampling and processing of electrical equipment/circuit signature/characteristics data can be conducted and transmitted for reporting near instantaneously. The sampling can be conducted in real time. The signature/characteristics data can be outputted for review very quickly (e.g. within seconds of the data being sampled). Early action/intervention can then be carried out to reduce risk of equipment/circuit failure and to take pre-emptive action to replace or modify electrical equipment or its power supply.

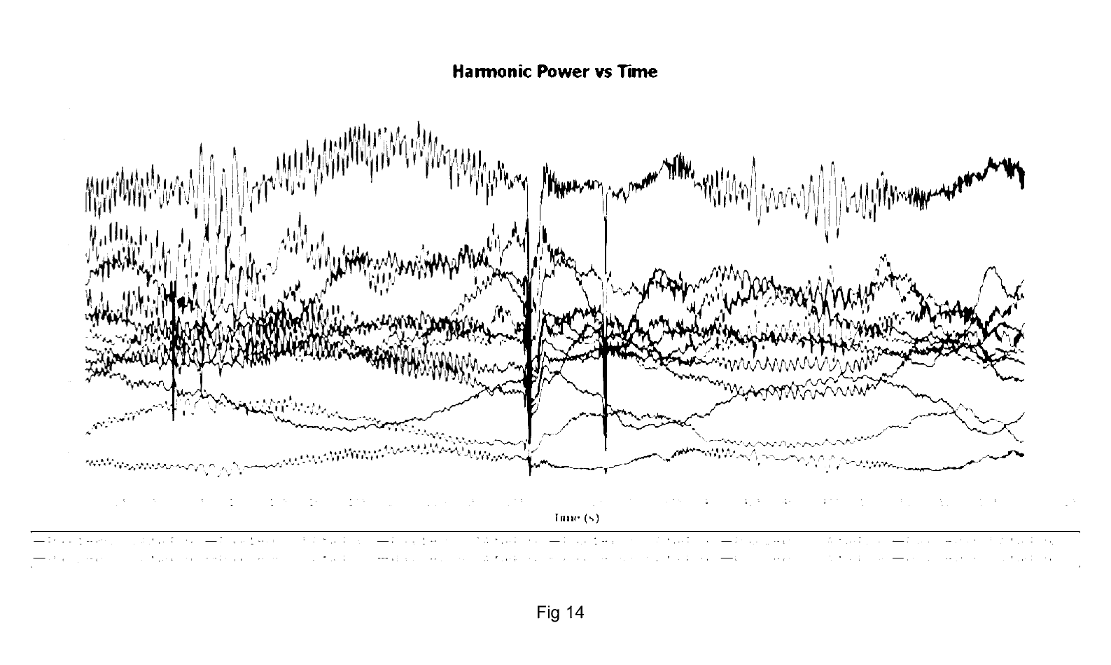

FIG. 14 shows a sample of analysed electrical features within harmonics of power versus time for a signature identifying a particular electrical device as a load on an electrical circuit.

The device relating to FIG. 14 is an electrically powered air compressor. It will be appreciated that analysis of the harmonics could be any electrical device, the harmonics differing between devices, but the feature of assessing the harmonics of the device as a signature/identifier for the device remains the same.

Each electrical device has its own unique electrical feature or features. Similar devices have similar features. Consequently, once the feature set of a type of device (make, model, rating etc.) is recorded, any similar device which has a matching feature set can also be identified, even if connected in a completely different electrical circuit, building, site or location.

Analysis conducted by the system of the present invention of the feature(s) of a number of similar devices can develop a range of expected variables in the electrical characteristics. For example, older similar devices may have a somewhat different characteristics to newer devices of the same type. An electrical device of that type subsequently under analysis may fit within the range of harmonics for the older and newer devices. If, however, the electrical device under analysis falls outside of the expected range(s), an alert may be given and/or the device assessed for faults.

FIG. 14 shows the higher order power (current (I) and voltage (V)) harmonics 3, 5, 7 and 9 for each phase of a three phase air compressor. Further current and voltage harmonics for the electrical device(s) can also be assessed within the scope of the present invention.

Preferably, multiple features are sampled from multiple harmonics. For example, up to 49 harmonics may be sampled, or a selection of harmonics sampled from the 49 harmonics. It will be appreciated that the greater the number of harmonics sampled the greater the resolution for identifying a device and separating a signature for a device from signatures of other devices.

Preferably, a number of harmonics are sampled to identify characteristics of the electrical waveform made up of multiple harmonics.

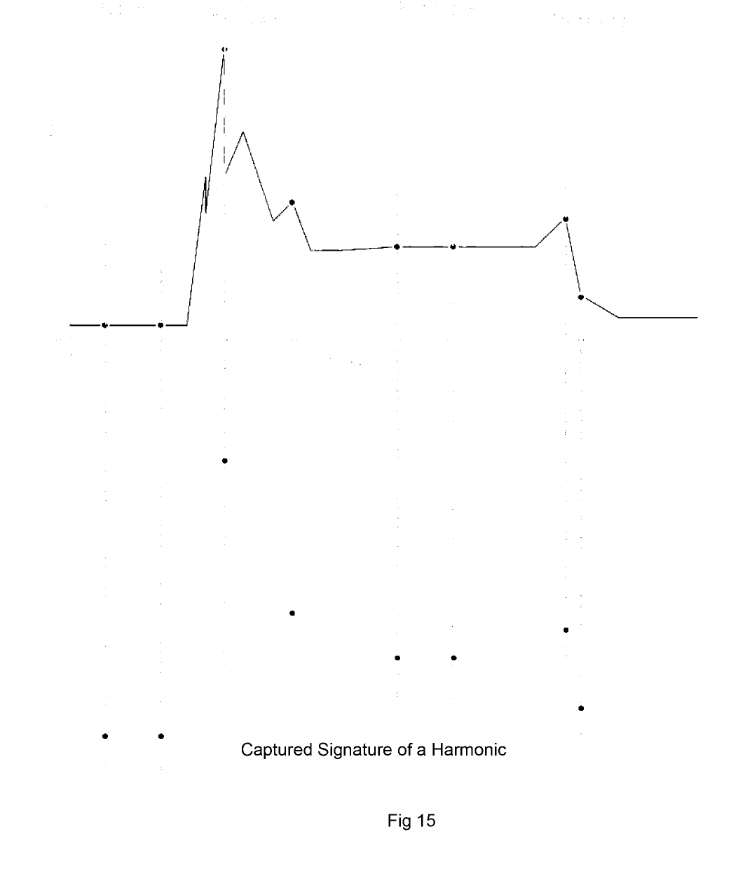

As shown in FIG. 15, four states of the sampling operation are identified a). Standby/Off, b). Start Transient, c). Run State, d). Stop Transient.

Preferably, at least two points are identified/plotted per operational state.

The power rating of the device is identified, such as from the magnitude of the harmonic(s).

Additional sampling points can be identified/plotted, if required, on subsequent operations, such as for greater resolution or more detailed electrical fault/signal variation detail. The sampled points are stored for reference.

Data relating to electrical features from sampled waveform of one or more devices at other locations and/or in other circuits can be used to augment the known characteristics for a device over time. This helps to improve knowledge of the device and accepted variations in the electrical identity for correctly functioning devices falling within a range of electrical characteristics as might be expected due to small variations in manufacture for similar devices.

Future deviations from the plotted points indicate degradation or potential failure of device.

1-30. (canceled)

31. A method of assessing at least one electrical device connected to an electrical circuit, the at least one electrical device in operation providing an electrical load, the method including assessing at least one electrical feature of the at least one electrical device, and determining at least one electrical characteristic of the at least one electrical device.

32. The method of claim 31, including storing the at least one electrical characteristic or the at least one electrical feature, or storing the at least one electrical characteristic and the at least one electrical feature, in a record.

33. The method of claim 32, the record including searchable record of multiple said characteristics or multiple features of multiple said electrical devices, or the record including searchable record of multiple said characteristics and multiple features of the electrical devices.

34. The method of claim 31, the characteristic(s) or feature(s) used as a reference or benchmark for other electrical devices for assessment, including identifying other electrical devices with the same or similar characteristic(s) and/or feature(s) as the same type of device or within a family of electrical devices

35. The method of claim 31, wherein the assessed feature(s) or characteristics include one or more of current harmonics, voltage harmonics or power harmonics.

36. A system for assessing or monitoring performance of electrical devices connected to at least one electrical circuit, the system including at least one electrical information collector connected to a said electrical circuit, at least one processor receiving and processing electrical information relating to at least one electrical feature, characteristic or harmonic of operation of the respective electrical device, a transmitter sending the processed electrical information to at least one remote location, a means for generating a number unique electrical characteristics derived from the at least one feature relating to the electrical device.

37. The system of claim 36, including access to a record of the at least one characteristic and/or the at least one feature of a number of said electrical devices.

38. The system of claim 36, including a comparator to compare information of two said electrical devices.

39. The system of claim 36, including assignment means to assign an identifier to the electrical device being assessed or monitored.

40. A network of multiples of the system of claim 36, the systems sharing access to the records/data containing the records.

41. The method of claim 31, further including the steps of:
obtaining electrical usage data relating to at least one electrical energy usage characteristic of the at least one electrical device in use;
identifying at least one electrical energy use feature relating to the at least one electrical energy usage characteristic of the at least one electrical device in use.

42. The method of claim 41, wherein the at least one electrical usage characteristic of the at least one electrical device includes one or both of current and voltage characteristics of the respective electrical device.

43. The method of claim 41, wherein the at least one electrical use characteristic is obtained periodically by sampling the electrical energy usage characteristic of the respective at least one device in use.

44. The method of claim 43, wherein the sampling is conducted over a period of time.

45. The method of claim 41, the at least one electrical characteristic including at least one energy use signature of the at least one electrical device include electrical current or voltage harmonics characteristics, or electrical current and voltage harmonics characteristics.

46. The method of claim 45, wherein the harmonics characteristics include one or more sampled current or voltage values over time, or one or more sampled current and voltage values over time.

47. The method of claim 41, wherein at least one said electrical device has an electrical energy use identification set of characteristics associated therewith, the electrical energy use signature identifying that device as a particular electrical load.

48. The method of claim 47, wherein the obtained electrical energy use set of characteristics is compared with a known said identification characteristics for a particular type or model of said electrical device, and any variation(s) in electrical energy use characteristics between the obtained characteristics and known identification is/are used to determine any need for modification of electrical energy usage.

49. The method of claim 41, wherein the obtained electrical energy use characteristic is used to establish the identification of subsequent use for that electrical device.

50. The method of claim 41, wherein the identification is assigned as an identification code for other like types or models of the device in other electrical circuits.

51. The method of claim 41, including using the at least one electrical energy use characteristic to determine a maintenance or replacement strategy for the at least one electrical device.

52. The method of claim 41, whereby features of an electrical energy use waveform are sampled to identify one or more electrical characteristics of a said electrical device.

53. The method of claim 52, including modifying the electrical character set of a said electrical device by relating the features/characteristics to the electrical identities from sampled features of one or more other said electrical devices at other locations or in other circuits, or at other locations and in other circuits.

54. The method of claim 53, whereby deviations over time from sampled harmonics are used to identify or indicate degradation or potential failure of the at least one electrical device.
